(19) United States
(12) Patent Application Publication
(10) Pub. No.: US 2009/0230522 A1
(43) Pub. Date: Sep. 17, 2009

(54) Method for producing a semiconductor device and the semiconductor device

(75) Inventor: Seisei Oyamada, Tokyo (JP)

Correspondence Address: COLLARD & ROE, P.C., 1077 NORTHERN BOULEVARD, ROSLYN, NY, 11576, US

(73) Assignee: Technology Alliance Group, Inc.

(21) Appl. No.: 12/077,174

(22) Filed: Mar. 17, 2008

(51) Int. Cl. H01L 23/495; H01L 21/00

(52) U.S. Cl. 257/676; 438/462; 257/E23.031; 257/E21.001

(57) ABSTRACT

In a method of manufacturing a semiconductor device which has rear electrodes extended from a front surface to a rear surface of a substrate, the rear electrodes are formed from a side of the front surface by forming a groove on the front surface, by forming a metal film on the groove, and by removing the substrate from a rear surface until the metal film is exposed on a bottom of the groove.

### BACKGROUND OF THE INVENTION

This invention relates to a method of producing a semiconductor device and a semiconductor device produced by the method and, in particular, to a method of producing a semiconductor device which is capable of forming a wiring structure which reaches to a rear surface of a substrate in a low-cost process and a semiconductor device produced by the method.

With reduction in size and improvement in function of an electronic apparatus in recent years, a semiconductor device forming the electronic apparatus is required to be reduced in size and profile, improved in function, and increased in reliability. Under the circumstances, a method of mounting a semiconductor chip is shifted from a pin-insertion package to a surface-mount package. Recently, use is made of a bare-chip mounting technique in which a bare semiconductor chip prior to packaging (hereinafter will be referred to as a “bare chip”) is directly mounted to a printed board. Furthermore, mounting techniques called a chip size package (CSP) and a wafer scale package (WSP) are used also. In the chip size package, an interposer is used instead of a lead frame. In the wafer scale package, the chip size package is prepared in a wafer size or level.

Referring to FIGS. 1 and 2A to 2D, description will be made of a process of forming a rear electrode in a conventional method of producing a wafer scale package (for example, see Japanese Unexamined Patent Application Publication (JP-A) No. 2005-159103).

At first, referring to FIGS. 1 and 2A, a silicon wafer 501 prior to formation of semiconductor elements is subjected to laser beam processing, wet etching, or dry etching to form a plurality of through holes 502. Thereafter, as illustrated in FIG. 2B, a surface of the silicon wafer 501 is sintered in an O₂ atmosphere at a temperature between 700 and 800° C. to form an insulating oxide film (SiO₂) 503.

Next referring to FIG. 2C, the through holes 502 are filled with a metal 504 deposited by sputtering, CVD, plating, or the like. In this event, the metal 504 is also deposited on the surface of the insulating oxide film 504, as shown in FIG. 2C. The metal 504 is subjected to grinding and polishing and is left on front and rear surfaces of the substrate. Thus, electrodes 504a are formed as illustrated in FIG. 2D.

### SUMMARY OF THE INVENTION

However, the above-mentioned conventional process of forming a rear electrode requires a number of additional steps, including formation of the through holes, formation of the insulating film, filling of the metal, grinding, and polishing and, therefore, can not be executed at a low cost. Furthermore, in the above-mentioned process, the semiconductor elements can not be formed after the rear electrode is formed.

In view of the above, it is an object of this invention to provide a method of producing a semiconductor device, which is capable of producing a wiring structure to be connected to a rear surface of the substrate in a low-cost process, and to provide a semiconductor device produced by the method.

According to this invention, there is provided a method of producing a semiconductor device, in which a substrate is cut along a scribe line into a plurality of device regions to produce a plurality of semiconductor devices. The method comprises a half cutting step of executing half-cut dicing, from a front surface of the substrate where the device regions are formed, on a cut area along the scribe line between the device regions to form a groove on the substrate; a protective film forming step of forming a protective film on a cut surface of the groove; a metal film forming step of forming a metal film on the front surface of the substrate; a wiring structure forming step of patterning the metal film to form a wiring structure; and a grinding step of grinding a rear surface of the substrate opposite to the front surface to expose the wiring structure on the rear surface.

Preferably, the half cutting step is performed after a resist is applied to the front surface of the substrate where the device regions are formed and the metal film forming step is performed after the resist is removed.

Preferably, the wiring structure is provided with a stand-off portion.

Preferably, the wiring structure is substantially flush with the rear surface.

Preferably, the semiconductor device is a chip size package (CSP) or a wafer scale package (WSP).

Preferably, the wiring structure includes a rear electrode.

Preferably, the wiring structure includes a wire for connection with another chip in case where another chip is mounted.

Preferably, the wiring structure includes a power line for supplementing a power supply.

Preferably, the wiring structure includes a heat sink.

According to this invention, there is also provided a semiconductor device produced by the above-mentioned method.

According to this invention, there is also provided a semiconductor device of a surface-mount type. The semiconductor device comprises a pad formed on a front surface of a substrate where a device region is formed; a protective film formed on a side surface of the substrate; and a wiring structure electrically connected to the pad and formed on the protective film to extend to a rear surface of the substrate.

Preferably, the wiring structure is provided with a stand-off portion.

Preferably, the wiring structure is substantially flush with the rear surface.

Preferably, the semiconductor device is a chip size package (CSP) or a wafer scale package (WSP).

According to this invention, there is provided a method of producing a semiconductor device, in which a substrate is cut along a scribe line into a plurality of device regions to produce a plurality of semiconductor devices. The method comprises a half cutting step of executing half-cut dicing, from a front surface of the substrate where the device regions are formed, on a cut area along the scribe line between the device regions to form a groove on the substrate; a protective film forming step of forming a protective film on a cut surface of the groove; a metal film forming step of forming a metal film on the front surface of the substrate; a wiring structure forming step of patterning the metal film to form a wiring structure; and a grinding step of grinding a rear surface of the substrate opposite to the front surface to expose the wiring structure on the rear surface. Thus, in a typical process of semiconductor production, a cut area along a scribe line is halfway cut to form a groove. By utilizing the groove, most of processing steps can be executed on the side of a surface (namely, a front surface side) of a substrate where semiconductor elements are formed. Accordingly, a wiring structure connected to a rear surface of the substrate can be formed in a less number of simple steps. It is therefore possible to provide a method of producing a semiconductor device, which is capable of forming a wiring structure connected to a rear surface of a substrate in a low-cost process.

### BRIEF DESCRIPTION OF THE DRAWINGS

FIG. 1 is a schematic plan view for describing a process of forming, in a conventional method of producing a semiconductor device, a wiring structure which reaches to a rear surface of a substrate;

FIGS. 2A to 2D are schematic sectional views for describing the process of forming a rear wiring structure in the conventional method;

FIG. 3 is a schematic plan view for describing a process of forming a rear wiring structure in a method of producing a semiconductor device according to a first embodiment of this invention;

FIGS. 4A to 4K are schematic sectional views for describing the process of forming a rear wiring structure in the method according to the first embodiment of this invention;

FIG. 5A is a schematic sectional view showing a first modification of a semiconductor device;

FIG. 5B is a schematic sectional view showing a second modification of a semiconductor device;

FIG. 6A is a schematic plan view of a characteristic part of a semiconductor device according to a second embodiment of this invention;

FIG. 6B is a schematic sectional view taken along a line 6B-6B in FIG. 6A;

FIG. 7A is a schematic plan view of a characteristic part of a semiconductor device according to a third embodiment of this invention;

FIG. 7B is a schematic sectional view taken along a line 7B-7B in FIG. 7A;

FIG. 8A is a schematic plan view of a characteristic part of a semiconductor device according to a fourth embodiment of this invention; and

FIG. 8B is a schematic sectional view taken along a line 8B-8B in FIG. 8A.

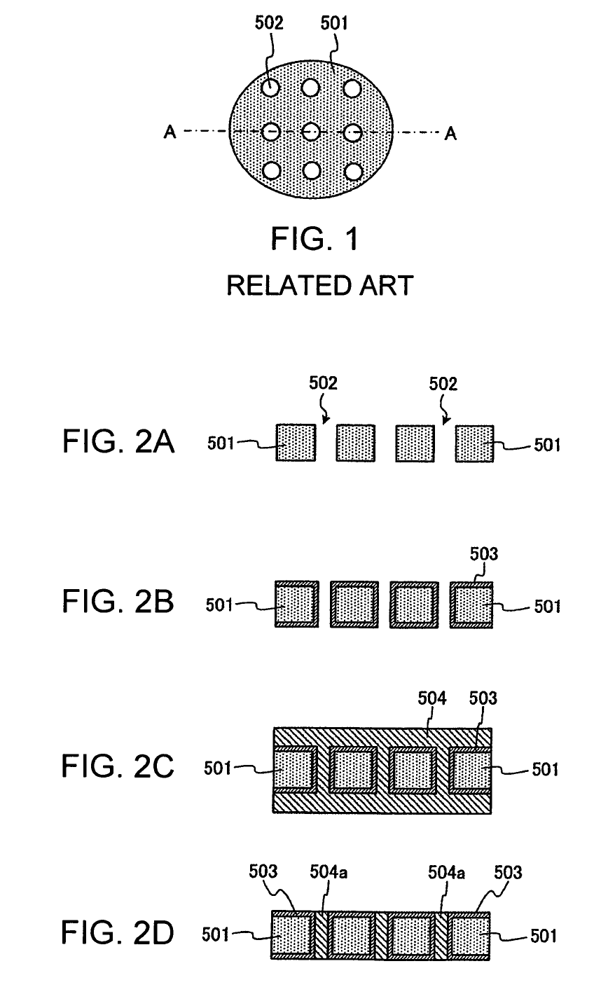

### DESCRIPTION OF THE EXEMPLARY EMBODIMENTS

Now, several exemplary embodiments of this invention will be described with reference to the drawing. It is noted here that this invention is not limited to the following embodiments. Components in the following embodiments encompass those which are readily envisaged by a skilled person or those which are substantially equivalent.

### First Embodiment

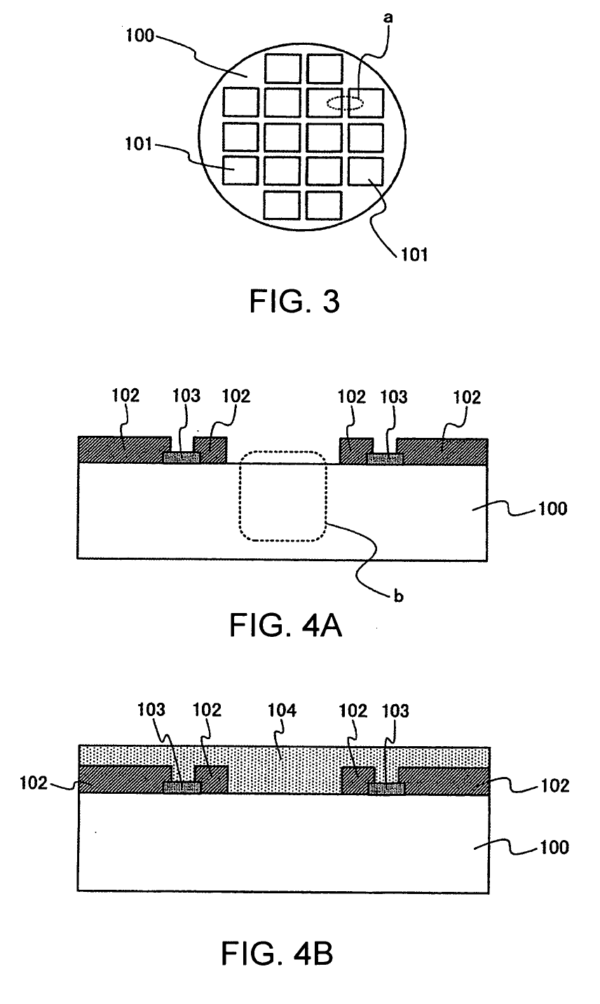

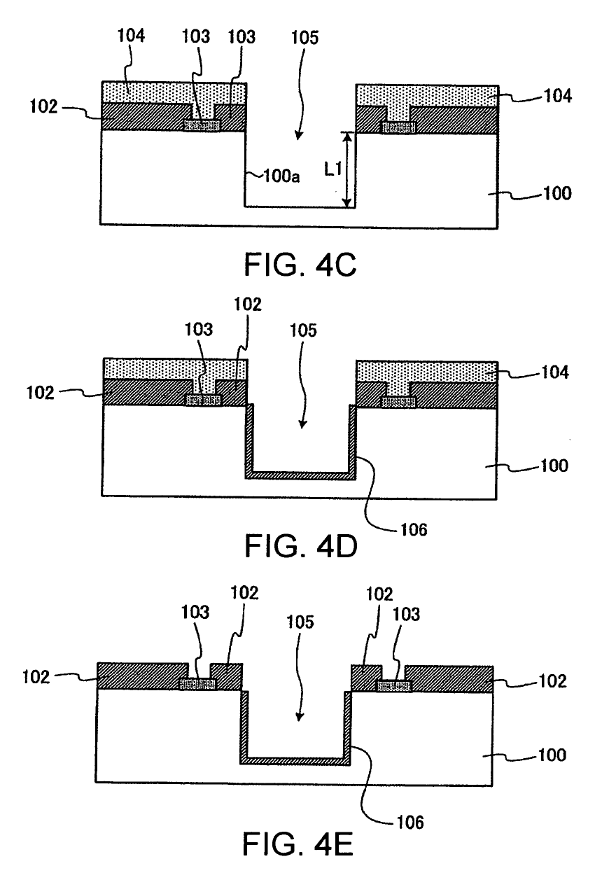

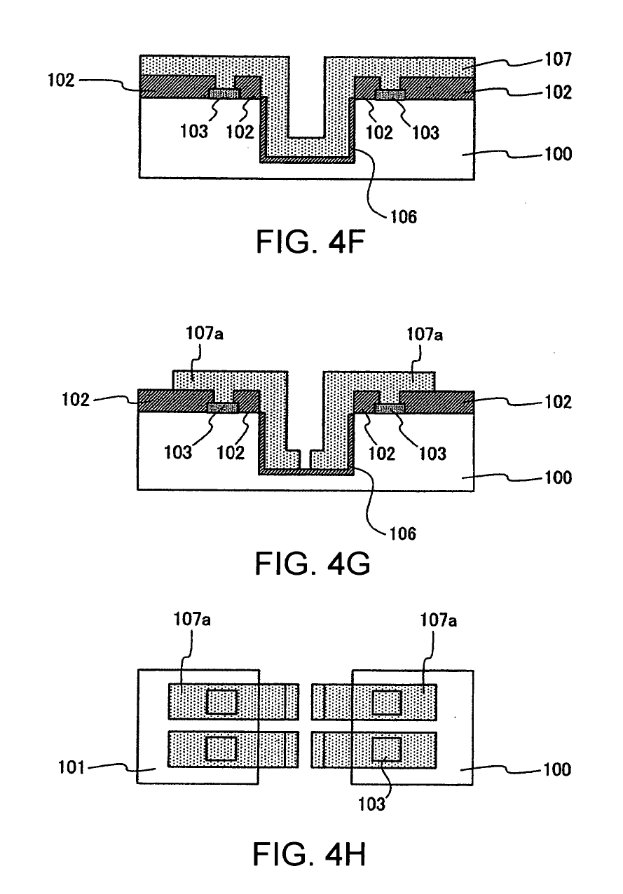

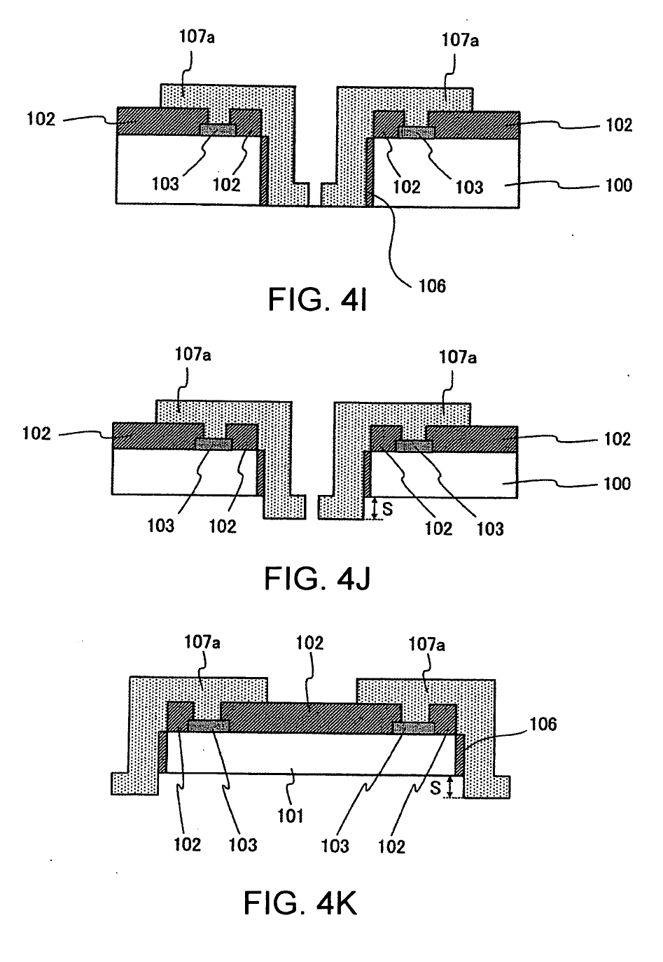

Referring to FIGS. 3 and 4A to 4K, description will be made of a process of forming a wiring structure in a method of producing a semiconductor device according to a first embodiment of this invention. In the first embodiment, a rear electrode is formed as a wiring structure.

In the method according to the first embodiment, when a plurality of semiconductor devices are produced by cutting a substrate having a plurality of LSI device regions formed thereon to separate the device regions, a cut area along a scribe line is halfway cut to form a groove on a front surface of the substrate. The depth of the groove corresponds to a wiring length of the rear electrode. In the following, description will be made of production of a wafer scale package or a chip scale package by way of example.

Referring to FIG. 3, a silicon (Si) substrate 100 after formation of a plurality of LSI devices has a plurality of LSI device regions 101. A part “a” surrounded by a broken line in FIG. 3 is shown in an enlarged sectional view in FIG. 4A.

Referring to FIG. 4A, the silicon substrate 100 is shown in section over an area across a scribe line. An LSI wiring layer 102 is formed on the silicon substrate 100 and includes a plurality of LSI wires protected by an insulating film (not shown). On the silicon substrate 100, a plurality of pads 103 are formed also. A part “b” surrounded by a dotted line is a cut area along the scribe line.

Referring to FIG. 4B, the silicon substrate 100 after completion of device formation is coated with a resist 104 which also serves to prevent oxidization of the pads 103. Referring to FIG. 4C, half-cut dicing is executed on the cut area “b” along the scribe line from an upper surface of the resist 104. As a result, the silicon substrate 100 is provided with a groove 105 having a depth L1 to form a cut surface 100a where silicon is exposed. For example, the depth L1 is within a range between 100 and 200 μm. The depth L1 of the groove 105 corresponds to a wiring length of a rear electrode.

Referring to FIG. 4D, the cut surface 100a is cured in an oxygen (O₂) atmosphere to form an insulating film 106 as a protective film. Thereafter, as illustrated in FIG. 4E, the resist 104 is removed and an entire surface is cleaned. Referring to FIG. 4F, throughout the entire surface, a metal such as Cu or Al is deposited by sputtering or CVD to form a metal film 107. The metal film 107 has a thickness, for example, between 50 and 100 μm.

Referring to FIG. 4G, the metal film 107 is patterned to form a plurality of electrodes 107a which may serve as rear electrodes, as will become clear as the description proceeds. Specifically, the metal film 107 is coated with a resist. The resist is partially removed so that the resist is left on the metal film 107 at portions to be left as wires. Then, the metal film 107 is etched through the resist left as a mask and, thereafter, the resist is removed. Thus, the rear electrodes 107a are formed. Herein, in order to prevent peeling of the rear electrodes 107a, a protective film such as an epoxy resin film may be formed on the surface of the rear electrodes 107a. FIG. 4H is a schematic plan view corresponding to FIG. 4G.

Next referring to FIG. 4I, a rear surface of the silicon substrate 100 is entirely ground by the use of a back grinder and a polisher to expose the rear electrodes 107a on the rear surface of the silicon substrate 100. Thereafter, as illustrated in FIG. 4J, the rear surface of the silicon substrate 100 is entirely subjected to dry etching or wet etching to form stand-off portions S by the rear electrodes 107a. For example, the stand-off portions S have a height between 50 and 100 μm. Through the above-mentioned process, a semiconductor device provided with the rear electrodes 107a is produced as illustrated in FIG. 4K.

The semiconductor device illustrated in FIG. 4K has the pads 103 formed on a front surface of the silicon substrate 100 where the device regions are formed, the insulating film (protective film) 106 formed on side surfaces of the silicon substrate 100, and the rear electrodes (wiring structure) 107a electrically connected to the pads 103 and formed on the insulating film (protective film) 106 to extend to the rear surface. Therefore, a space for a rear wiring structure can be saved so that the semiconductor device is reduced in size and profile.

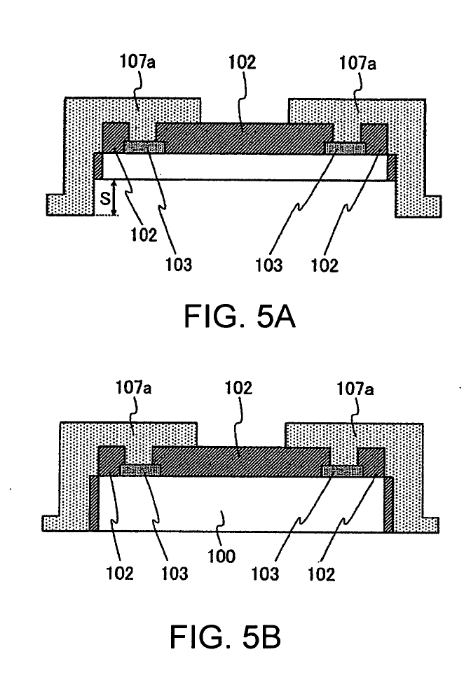

In case where a high-pin-count wafer scale or chip scale package is realized, the stand-off portions S may be increased in height as illustrated in FIG. 5A so as to relax thermal stress. Alternatively, as illustrated in FIG. 5B, no stand-off portions S may be formed.

As described above, the method according to the first embodiment comprises a resist applying step of applying the resist 104 onto the front surface of the silicon substrate 100 provided with a plurality of the device regions 101, a half cutting step of executing half-cut dicing, from the upper surface of the resist 104, on the cut area along the scribe line between the device regions 101 to form the groove 105 on the silicon substrate 100, an insulating film forming step of forming the protective film 106 on the cut surface 100a in the groove 105, a resist removing step of removing the resist 104, a metal film forming step of forming the metal film 107 throughout the entire surface of the silicon substrate 100, a wiring structure forming step of patterning the metal film 107 to form the rear electrodes (wiring structure) 107a, and a grinding step of grinding the rear surface of the silicon substrate 100 to expose the rear electrodes (wiring structure) 107a on the rear surface. Thus, in a typical process of semiconductor production, the cut area along the scribe line is halfway cut to form the groove. The depth L1 of the groove corresponds to the wiring length of the rear electrode. By utilizing the groove, most of processing steps can be executed on the side of the front surface where the device formation is performed. Thus, it is possible to form the rear electrodes in a less number of simple steps and to execute formation of the rear electrodes in a low-cost process.

### Second Embodiment

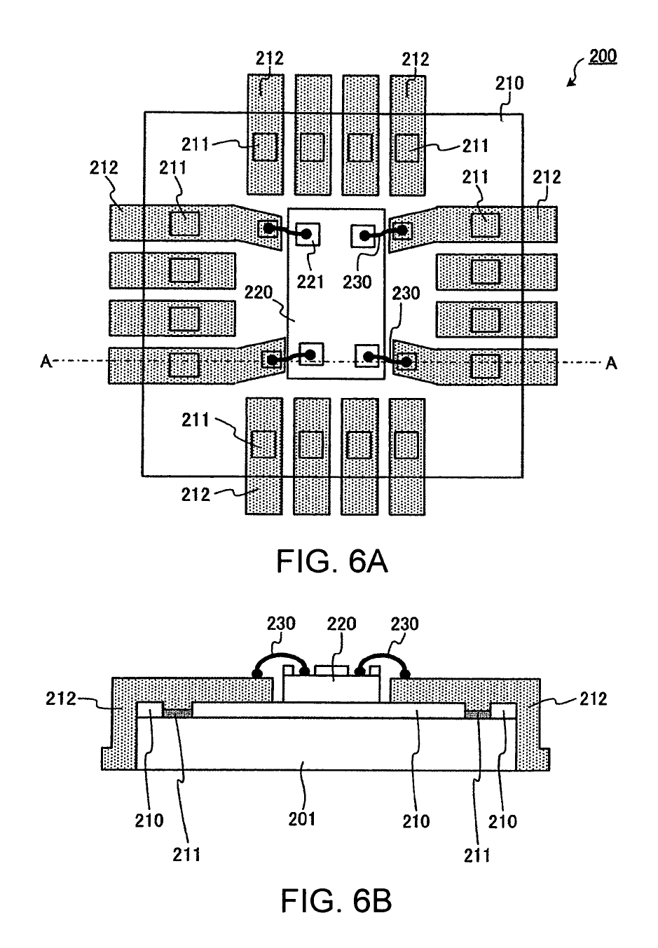

Referring to FIGS. 6A and 6B, description will be made of a method of producing a semiconductor device according to a second embodiment of this invention and a semiconductor device produced by the method. In the second embodiment, the process of forming a wiring structure of a semiconductor device according to the first embodiment is applied to rewiring of an LSI. In the second embodiment, wires in case where another chip is mounted on the LSI will be described as a wiring structure.

Referring to FIGS. 6A and 6B, a high-pin-count LSI chip 200 is formed on a silicon substrate 201. In the LSI chip 200, an LSI wiring layer 210 is formed on the silicon substrate 201 and includes a plurality of LSI wires protected by an insulating film. On the silicon substrate 201, a plurality of pads 211 are formed also. When an IC chip 220 is mounted, wires (wiring structure) 212 are formed in the manner similar to the first embodiment and a plurality of pads 221 of the IC chip 220 are connected to the wires (wiring structure) 212 by wire bonding using bonding wires 230. As illustrated in FIGS. 6A and 6B, the wiring structure 212 is extended on the rear surface of the silicon substrate 201, like in the first embodiment.

### Third Embodiment

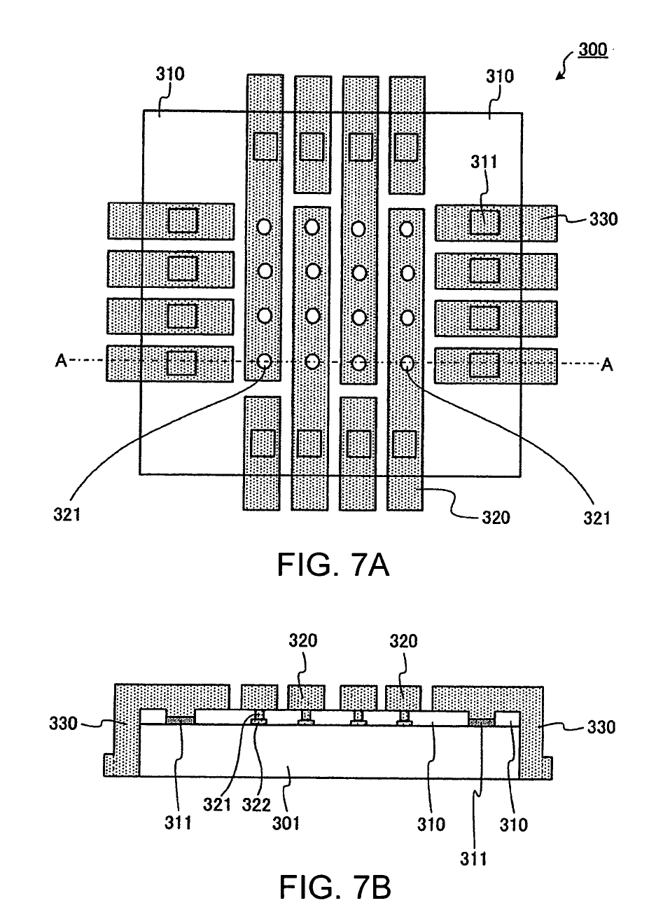

Referring to FIGS. 7A and 7B, description will be made of a method of producing a semiconductor device according to a third embodiment of this invention and a semiconductor device produced by the method. In the third embodiment, the process of forming a wiring structure of a semiconductor device according to the first embodiment is applied to formation of a power line for a power supply for an LSI. In the third embodiment, the power line will be described as a wiring structure.

Referring to FIGS. 7A and 7B, an LSI chip 300 has an LSI wiring layer 310 formed on a silicon substrate 301 and including a plurality of LSI wires protected by an insulating film. On the silicon substrate 301, a plurality of pads 311, a plurality of power contact vias 321, and a plurality of power posts 322 are formed also. A plurality of power lines (wiring structure) 320 and a plurality of wires (wiring structure) 330 are formed in the manner similar to the first embodiment and serve as the rear electrodes.

### Fourth Embodiment

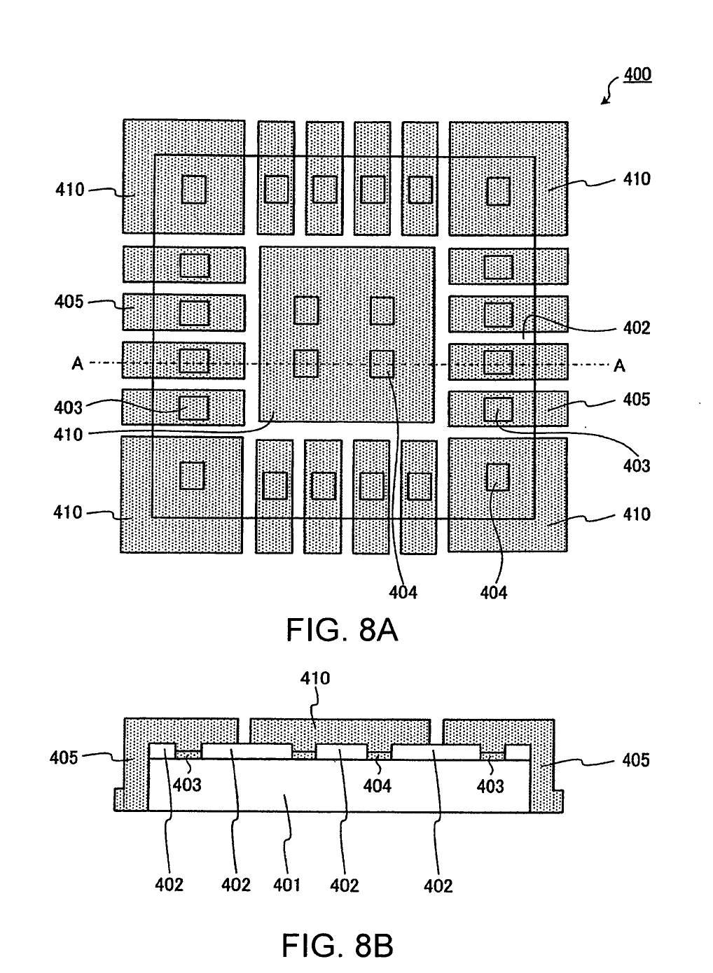

Referring to FIGS. 8A and 8B, description will be made of a method of producing a semiconductor device according to a fourth embodiment of this invention and a semiconductor device produced by the method. In the fourth embodiment, the process of forming a wiring structure of a semiconductor device according to the first embodiment is applied to formation of a heat sink (heat spreader for heat radiation). In the fourth embodiment, a heat sink will be described as a wiring structure.

Referring to FIGS. 8A and 8B, an LSI chip 400 has an LSI wiring layer 402 formed on a silicon substrate 401 and including a plurality of LSI wires protected by an insulating film. On the silicon substrate 401, a plurality of pads 403 and a plurality of heat-radiation junction connectors 404 are formed also. A plurality of heat-radiation heat spreaders (wiring structure) 410 and a plurality of wires (wiring structure) 405 are formed in the manner similar to the first embodiment.

The method of producing a semiconductor device according to this invention and the semiconductor device produced by the method are widely applicable to semiconductor devices of a surface-mount type. For example, the method and the semiconductor device are suitably used for a chip size package (CSP) or a wafer scale package (WSP).

Although this invention has been described in conjunction with the exemplary embodiments thereof, this invention is not limited to the foregoing embodiments but may be modified in various other manners within the scope of the appended claims.

What is claimed is:

1. A method of producing a semiconductor device, in which a substrate is cut along a scribe line into a plurality of device regions to produce a plurality of semiconductor devices, the method comprising:
a half cutting step of executing half-cut dicing, from a front surface of the substrate where the device regions are formed, on a cut area along the scribe line between the device regions to form a groove on the substrate;
a protective film forming step of forming a protective film on a cut surface of the groove;
a metal film forming step of forming a metal film on the front surface of the substrate;
a wiring structure forming step of patterning the metal film to form a wiring structure; and
a grinding step of grinding a rear surface of the substrate opposite to the front surface to expose the wiring structure on the rear surface.

2. The method according to claim 1, wherein:
the half cutting step is performed after a resist is applied to the front surface of the substrate where the device regions are formed;
the metal film forming step being performed after the resist is removed.

3. The method according to claim 1, wherein the wiring structure is provided with a stand-off portion.

4. The method according to claim 1, wherein the wiring structure is substantially flush with the rear surface.

5. The method according to claim 1, wherein the semiconductor device is a chip size package (CSP) or a wafer scale package (WSP).

6. The method according to claim 1, wherein the wiring structure includes a rear electrode.

7. The method according to claim 1, wherein the wiring structure includes a wire for connection with another chip in case where another chip is mounted.

8. The method according to claim 1, wherein the wiring structure includes a power line for supplementing a power supply.

9. The method according to claim 1, wherein the wiring structure includes a heat sink.

10. A semiconductor device produced by the method according to claim 1.

11. A semiconductor device of a surface-mount type, comprising:
a pad formed on a front surface of a substrate where a device region is formed;
a protective film formed on a side surface of the substrate; and
a wiring structure electrically connected to the pad and formed on the protective film to extend to a rear surface of the substrate.

12. The semiconductor device according to claim 11, wherein the wiring structure is provided with a stand-off portion.

13. The semiconductor device according to claim 11, wherein the wiring structure is substantially flush with the rear surface.

14. The semiconductor device according to claim 11, wherein the semiconductor device is a chip size package (CSP) or a wafer scale package (WSP).
